(19) United States
(12) Patent Application Publication
(10) Pub. No.: US 2012/0033365 A1
(43) Pub. Date: Feb. 9, 2012

(54) SLIDING MODULE FOR PORTABLE COMMUNICATION DEVICE

(75) Inventor: Hyun-Suk SHIN, Gyeonggi-do (KR)

(73) Assignee: SAMSUNG ELECTRONICS CO., LTD., Gyeonggi-Do (KR)

(21) Appl. No.: 13/198,044

(22) Filed: Aug. 4, 2011

(30) Foreign Application Priority Data
Aug. 6, 2010 (KR) 10-2010-0076039

(51) Int. Cl. H05K 5/00

(52) U.S. Cl. 361/679.01

(57) ABSTRACT

A sliding module includes a main member, a sliding member for sliding in engagement with the main member, guide members formed at both ends of the main member, and guide rails slidably engaged with the guide rails in a portable communication device, in which a contact engagement portion is provided at a guide member, a rail contact portion is provided at a guide rail, and a sheet portion is provided at the contact engagement portion to slidably engage the guide rail with the rail contact portion.

### CLAIM OF PRIORITY

This application claims priority under 35 U.S.C. §119 to a Korean Patent Application filed in the Korean Intellectual Property Office on Aug. 6, 2010 and assigned Serial No. 10-2010-0076039, the contents of which are incorporated herein by reference.

### BACKGROUND OF THE INVENTION

1. Field of the Invention

The present invention relates to a sliding module for a portable communication device.

2. Description of the Related Art

A “portable communication device” generally refers to a device that enables a user to conduct wireless communication with the other party. Depending on their designs, portable communication devices are typically classified, into a bar type, a flip type, and a folder type. A bar-type terminal has a single housing shaped into a bar. A flip-type terminal is configured so as to have a bar-shaped housing and a flip that are rotatably engaged with each other by a hinge device. A folder-type terminal includes a folder that is rotatably engaged with a single bar-shaped housing.

According to opening mechanisms, portable communication devices are classified into a rotation type and a sliding type. Two housings are opened or closed by rotating, face to face, in a rotation-type terminal, whereas two housings are opened or closed by making a lengthwise movement, face to face, in a sliding-type terminal.

Referring to FIGS. 1 and 2, a sliding module 1 includes a sliding housing (not shown) that slides from a body housing (not shown), a main member 2 provided at the body housing, and a sliding member 3 provided at the sliding housing, in engagement with the main member 2 to move on the main member 2 in a conventional sliding-type portable communication device.

Guide rails 3a shaped into “ [symbol] ” are formed at both ends of the sliding member 3, and guide members 2a shaped into “ [symbol] ” are formed at both ends of the main member 2 for engagement with the guide rails 3a.

The guide rails 3a and the guide members 2a are formed of a metal. While the guide rails 3a are sliding on the guide members 2a, their metallic friction may make noise or produce scratches, thereby making the sliding unsmooth.

To avert this problem, outer portions 4 of the guide members 2a are formed of polyacetal (PolyOxyMethylene (POM)) resin through insert molding.

As shown, the “ [symbol] ”-shaped guide members are coated on the inner and outer surfaces by insert molding which in turn causes the sliding module to become thicker in the conventional sliding-type portable communication device. In addition, scratches are produced only at contact portions between the guide members and the guide rails in the sliding module of the conventional sliding-type portable communication device.

Accordingly, as evolving trend demands a slimmer communication device, there exists a need for fabricating a thin device at a contact portion between a guide member and a guide rail, without insert-molding of the contact portion to make the device chic and smaller.

### SUMMARY OF THE INVENTION

An aspect of embodiments of the present invention is to address at least the problems and/or disadvantages and to provide at least the advantages described below. Accordingly, an aspect of embodiments of the present invention is to provide a sliding module in a sliding-type portable communication device, in which a thin sheet portion is formed at a contact portion of a guide member that contacts a guide rail without insert-molding of the contact portion, thus reducing the thickness of the contact portion of the guide member to make it stylish and slick while increasing the strength of the product.

Another aspect of embodiments of the present invention is to provide a sliding module in a sliding-type portable communication device, in which a thin sheet portion is formed at a guide member in order to reduce friction and scratches between the guide member and a guide rail during sliding, thus improving sliding and sensitivity of a product.

Another aspect of embodiments of the present invention is to provide a sliding module in a sliding-type portable communication device, in which a contact portion is formed at a guide member that contacts a guide rail to thereby obviate the need for insert-molding a portion of the guide member that contacts the guide rail, thus make a product slim and small and also reduce friction and scratches of the product.

A further aspect of embodiments of the present invention is to provide a sliding module in a sliding-type portable communication device, in which a thin layer is formed at a guide rail by coating the guide rail with pigment in order to make a product slim and small, reduce friction of the product, and increase the abrasion-proofness of the product.

In accordance with an embodiment of the present invention, a sliding module includes a main member, a sliding member for sliding in engagement with the main member, guide members formed at both ends of the main member, and guide rails slidably engaged with the guide rails in a portable communication device, in which a contact engagement portion is provided at a guide member, a rail contact portion is provided at a guide rail, and a sheet portion is provided at the contact engagement portion to slide the guide rail, in engagement with the rail contact portion.

In accordance with another embodiment of the present invention, a sliding module includes a main member, a sliding member for sliding in engagement with the main member, guide members formed at both ends of the main member, and guide rails slidably engaged with the guide rails in a portable communication device, in which a contact engagement portion is provided at a guide member, a rail contact portion is provided at a guide rail, and a contact portion is provided at the rail contact portion to slide the guide rail, in engagement with the contact engagement portion.

In accordance with a further embodiment of the present invention, a sliding module includes a main member, a sliding member for sliding in engagement with the main member, guide members formed at both ends of the main member, and guide rails slidably engaged with the guide rails in a portable communication device, in which a contact engagement portion is provided at a guide member, a rail contact portion is provided at a guide rail, and a thin layer is formed at the guide rail to slide the guide rail, in engagement with the contact engagement portion.

### BRIEF DESCRIPTION OF THE DRAWINGS

The above features and advantages of certain embodiments of the present invention will be more apparent from the following detailed description taken in conjunction with the accompanying drawings, in which:

FIG. 1 is a side sectional view of a sliding module in a conventional sliding-type portable communication device;

FIG. 2 is a perspective view of the sliding module in the conventional sliding-type portable communication device;

FIG. 3 is an exploded perspective view of a sliding module in a sliding-type portable communication device according to an embodiment of the present invention;

FIG. 4 is a perspective view of an engaged state of the sliding module according to the embodiment of the present invention;

FIG. 5 is an enlarged perspective view of a part A illustrated in FIG. 4;

FIG. 6 is a side view of a non-engaged state of the sliding module according to the embodiment of the present invention;

FIG. 7 is a side view of the engaged state of the sliding module according to the embodiment of the present invention;

FIG. 8 is a side view of another embodiment of a sheet portion in the sliding-type portable communication device according to the embodiment of the present invention;

FIG. 9 is an exploded perspective view of a sliding module in a sliding-type portable communication device according to another embodiment of the present invention;

FIG. 10 is a perspective view of an engaged state of the sliding module in the sliding-type portable communication device according to the second embodiment of the present invention;

FIG. 11 is an enlarged perspective view of a part B illustrated in FIG. 10;

FIG. 12 is a side view of a non-engaged state of the sliding module in the sliding-type portable communication device according to the second embodiment of the present invention;

FIG. 13 is a side view of the engaged state of the sliding module in the sliding-type portable communication device according to the second embodiment of the present invention; and

FIG. 14 is a side view of an engaged state of a sliding module in a sliding-type portable communication device according to a third embodiment of the present invention.

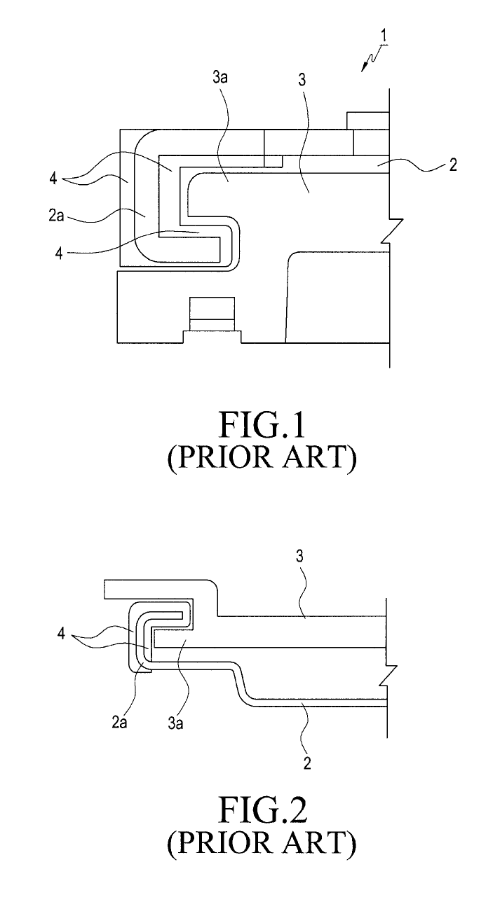

Throughout the drawings, the same drawing reference numerals will be understood to refer to the same elements, features and structures.

### DETAILED DESCRIPTION OF THE INVENTION

Reference will now be made in detail to the preferred embodiments of the present invention with reference to the accompanying drawings.

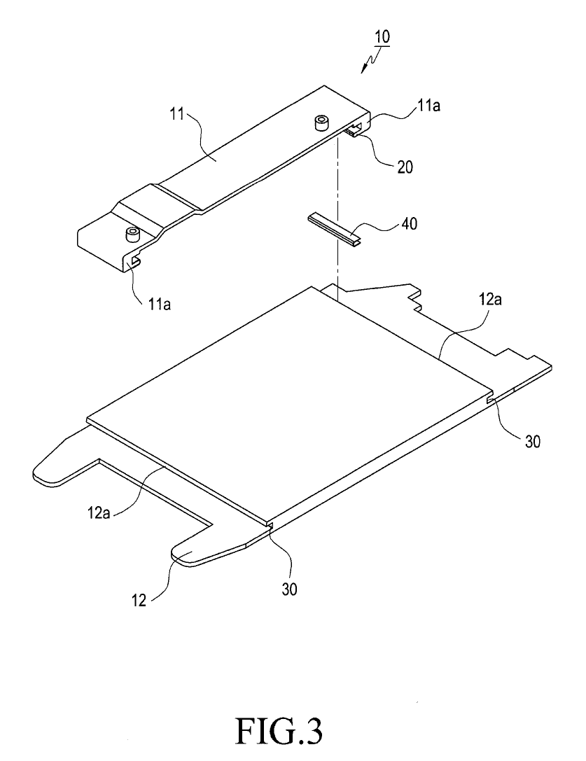

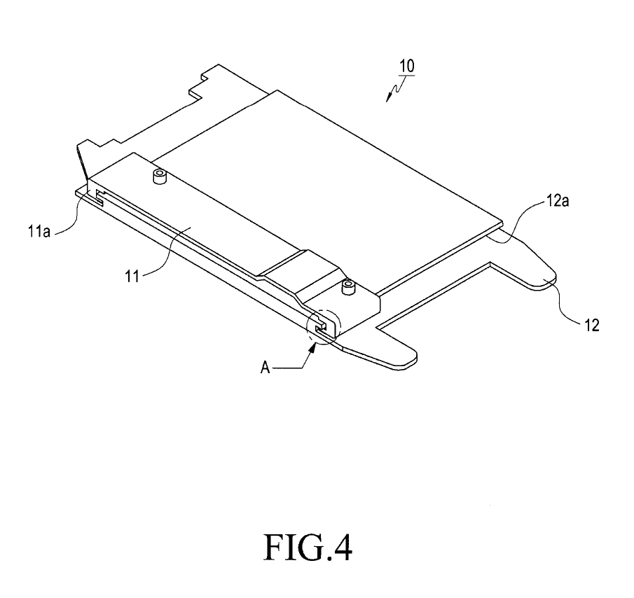

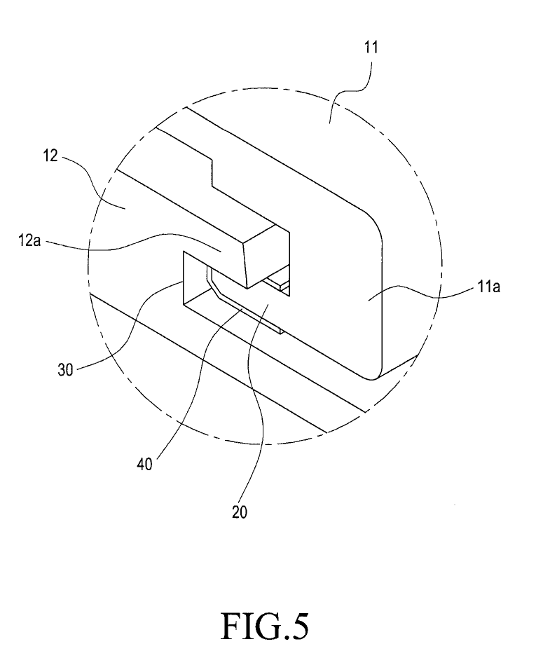

Referring to FIGS. 3 to 7, a sliding module 10 for a portable communication device (not shown) includes a main member 11, a sliding member 12 for sliding in engagement with the main member 11, guide members 11a, guide rails 12a, contact engagement portions 20, rail contact portions 30, and sheet portions 40. The guide members 11a are formed at both ends of the main member 11 so that the guide members 11a can slide along the guide rails 12a when it engages with the guide rails 12a. The guide rails 12a are formed at both ends of the sliding member 12 so that the guide rails 12a can slide during the engagement with the guide members 11a. The contact engagement portions 20 are provided at the guide members 11a to be slidably engaged with the later-described rail contact portions. The rail contact portions 30 are provided at the guide rails 12a to be slidably engaged with the contact engagement portions 20. The sheet portions 40 are provided at the contact engagement portions 20 to slide the guide rails 12a in relation with the rail contact portions 30.

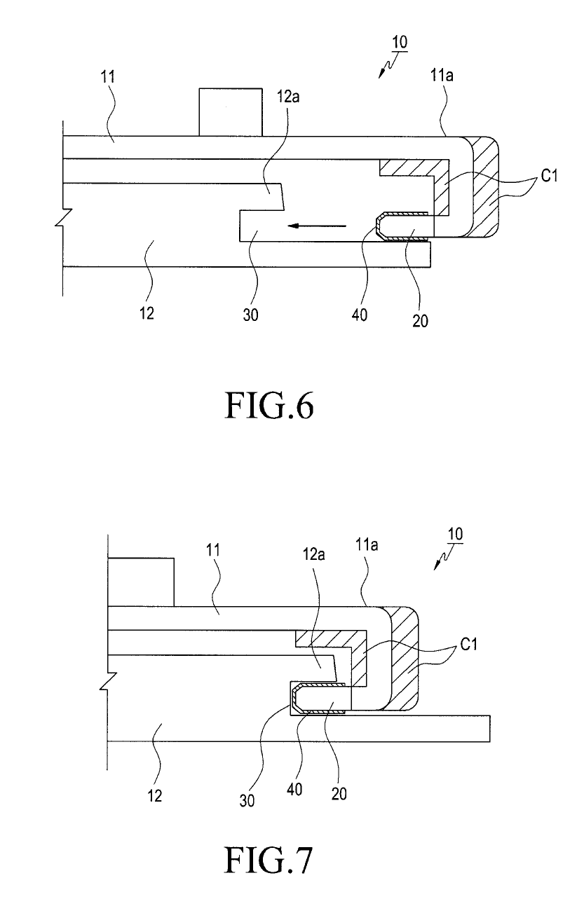

Referring to FIGS. 6 and 7, the contact engagement portions 20 are extended to a predetermined length to contact the rail contact portions 30. The contact engagement portions 20 are thinner than insert-molded portions C1 of the guide members 11a. The sheet portions 40 are shaped into “ [symbol] ” or “ [symbol] ” so as to surround the contact engagement portions 20.

The sheet portions 40 are formed of polyimide (PI), Teflon, or other material such as polyacetal.

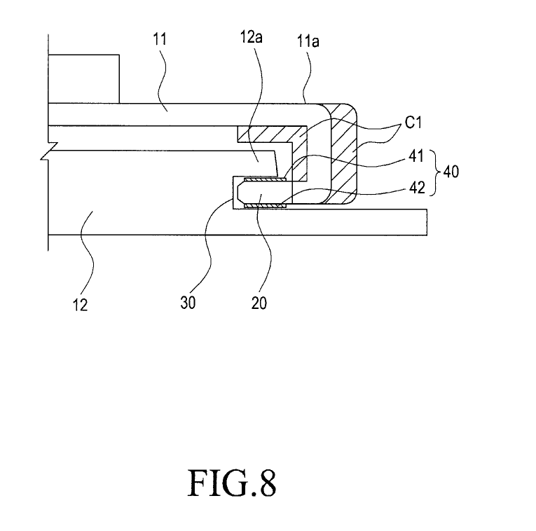

Referring to FIG. 8 illustrating another embodiment of the sheet portions 40, each of the sheet portions 40 includes first and second sheets 41 and 42 that contact frictional surfaces of a rail contact portion 30.

The sliding module according to the embodiment of the present invention is applicable mainly to, but not limited to a portable communication device (not shown). Thus, the inventive sliding module may be applicable to various types of terminals such as a bar type, a folder type, a swing type, and a sliding type.

A portable communication device according to the present invention covers a broad range of devices including mobile communication terminals operating in compliance with communication protocols for various communication systems, other information communication devices such as a Portable Multimedia Player (PMP), an MP3 player, a navigator, a game console, a laptop computer, an advertisement board, a TV, a digital broadcasting player, a Personal Digital Assistant (PDA), and a smart phone, electronic devices, multimedia devices, and their applications.

An operation of the sliding module having the above-described configuration in the portable communication device according to the embodiment of the present invention will be described in detail with reference to FIGS. 3 to 8.

Referring to FIGS. 3 to 7, the sliding module 10 of the portable communication device (not shown) includes the main member 11, the sliding member 12 that slides in engagement with the main member 11, the guide members 11a formed at both ends of the main member 11, the guide rails 12a formed at the sliding member 12 to slide in engagement with the guide members 11a, the contact engagement portions 20, the rail contact portions 30, and the sheet portions 40.

Referring to FIGS. 6 and 7, the contact engagement portions 20 are provided at the guide members 11a, extended to a predetermined length so that the contact engagement portions 20 may be brought into contact with the rail contact portions 30. The contact engagement portions 20 are thinner than the insert-molded portions C1 of the guide members 11a, and the extended contact engagement portions 20 are inserted into the sheet portions 40.

In this state, the contact engagement portions 20 inserted into the sheets 40 are slidably engaged with the rail contact portions 30.

When the sliding member 12 slides, the guide rails 12a also slide, that is, the rail contact portions 30 of the guide rails 12a also slide, as illustrated in FIG. 7.

Because the contact engagement portions 20 have the sheet portions 40 on their frictional surfaces, the rail contact portions 30 are brought into contact with the sheet portions 40. The resulting decrease in friction and scratches attributed to the use of the sheet portions 40 in turn improves the movement and sensitivity of the sliding member 12.

In addition, since the sheet portions 40 are formed thin, the product can be made slim and small, compared to a conventional sliding module whose thickness is increased due to insert molding. As a result, the product as a whole may have a slimmer stylish look and an increased strength. A thickness of the sheet portion ranges from 0.03 to 0.05 mm.

Referring to FIG. 8 illustrating another embodiment of the sheet portions 40, each of the sheet portions 40 includes the first and second sheets 41 and 42. The first and second sheets 41 and 42 are provided on the top and bottom surface of a contact engagement portion 20, thus contacting the frictional surfaces of the contact engagement portion 20.

As the first and second sheets 41 and 42 of the sheet portions 40 contact the frictional surfaces of the contact engagement portions 20, they in turn reduce friction caused by sliding, thus improving the sliding and further reducing scratches.

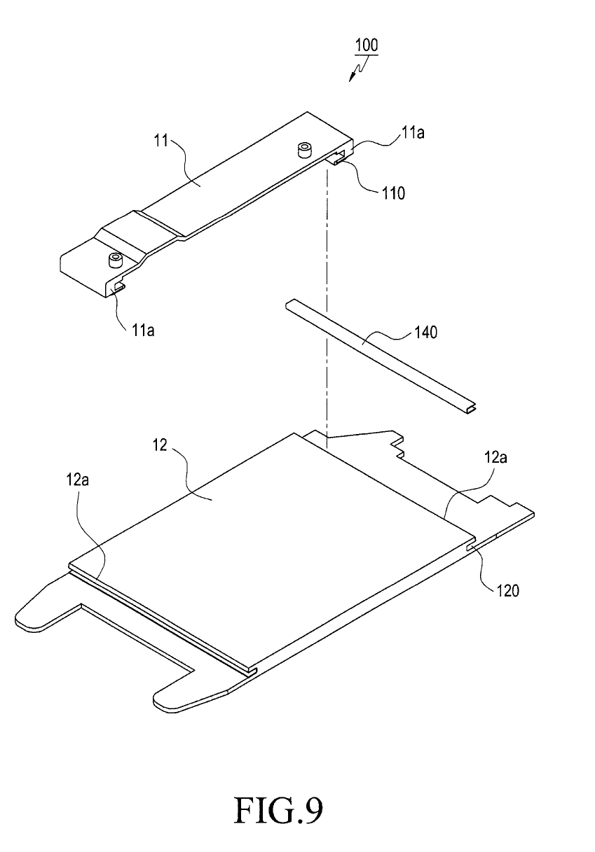

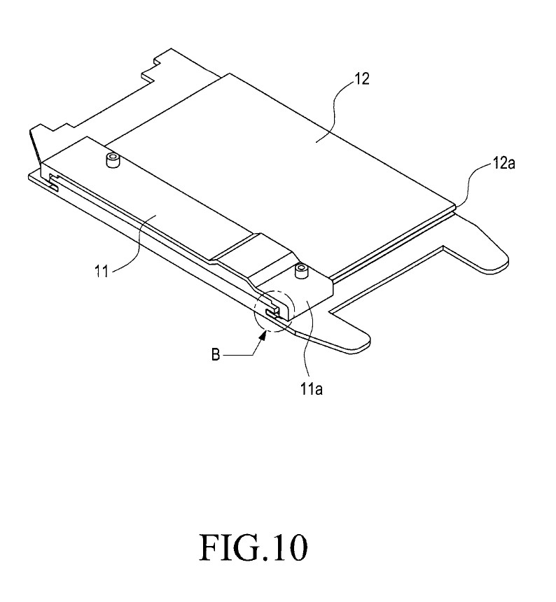

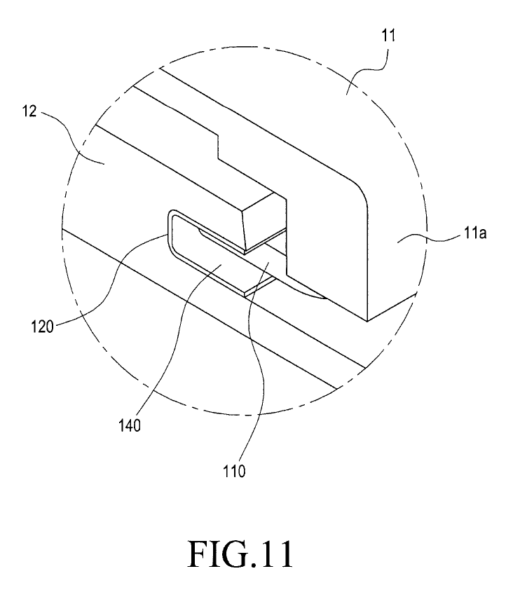

Hereinafter, an operation of the sliding module having the above-described configuration in the portable communication device according to yet another embodiment of the present invention will be described in detail with reference to FIGS. 9 to 13.

Referring to FIGS. 9 to 13, a sliding module 100 of a portable communication device (not shown) includes the main member 11, the sliding member 12 that slides in engagement with the main member 11, the guide members 11a formed at both ends of the main member 11, the guide rails 12a formed at the sliding member 12 to slide in engagement with the guide members 11a, contact engagement portions 110, rail contact portions 120, and contact portions 140.

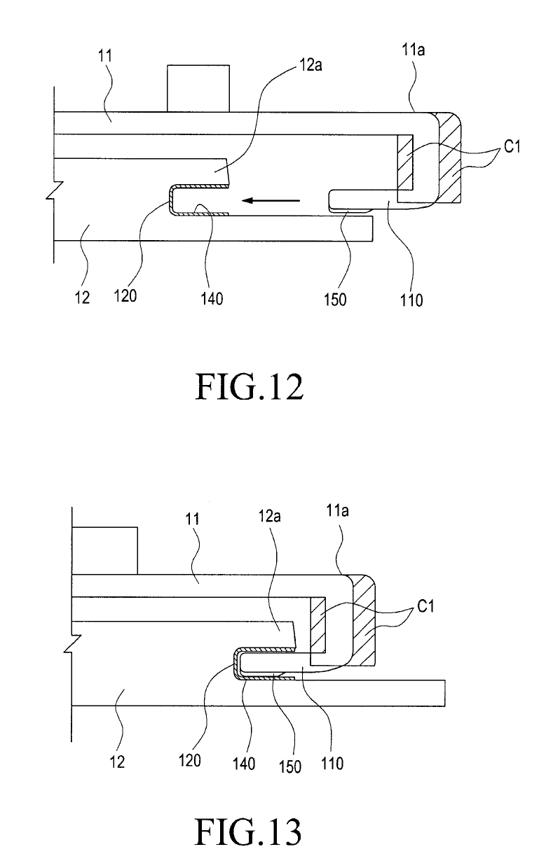

Referring to FIGS. 12 and 13, the contact engagement portions 110 are provided at the guide members 11a, extended to a predetermined length so that the contact engagement portions 110 may be brought into contact with the rail contact portions 120. The extended contact engagement portions 110 are thinner than the insert-molded portions C1 of the guide members 11a.

Referring to FIG. 13, the contact portions 140 are inserted into the rail contact portions 120. In this state, the extended contact engagement portions 110 are slidably engaged with the contact portions 140.

Because contact protrusions 150 are formed at the contact engagement portions 110 to contact frictional surfaces of the contact portions 140, the contact protrusions 150 are brought into contact with the frictional surfaces of the contact portions 140, when they are engaged with the contact portions 140, as illustrated in FIG. 13.

Then, when the sliding member 12 slides, the guide rails 12a also slide, that is, the rail contact portions 120 of the guide rails 12a also slide. At the same time, the contact portions 140 provided at the rail contact portions 120 move along.

Because the contact portions 140 slide in contact with the contact protrusions 150, friction and scratches between the contact engagement portions 110 and the rail contact portions 120 are reduced, thus improving the movement and sensitivity of the sliding member 12.

In addition, since the contact portions 140 are formed to a thickness of 0.05 mm at the rail contact portions 120 of the guide rails 12a without insert molding, the product as a whole can be made slim and small which in turn accomplishes a better look to the product as a whole and an increased strength.

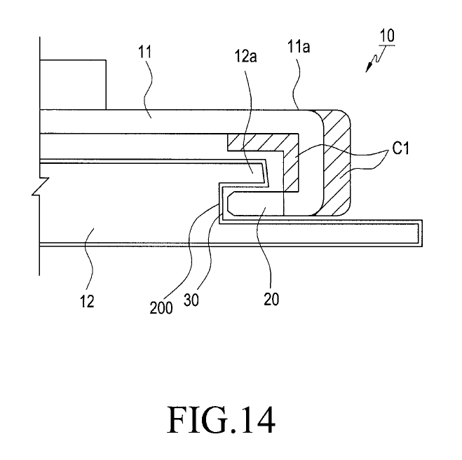

An operation of the sliding module having the above-described configuration in the portable communication device according to a further embodiment of the present invention will be described in detail with reference to FIG. 14.

Referring to FIG. 14, the sliding module 10 of a portable communication device (not shown) includes the main member 11, the sliding member 12 that slides in engagement with the main member 11, the guide members 11a formed at both ends of the main member 11, the guide rails 12a formed at the sliding member 12 to slide in engagement with the guide members 11a, the contact engagement portions 20, the rail contact portions 30, and thin layers 200.

Referring to FIG. 14, the contact engagement portions 20 are provided at the guide members 11a, extended to a predetermined length so that the contact engagement portions 20 may be brought into contact with the rail contact portions 30. The contact engagement portions 20 are thinner than the insert-molded portions C1 of the guide members 11a.

The thin layers 200 are coated on the guide rails 12a. The thin layers 200 are formed of pigment. Alternatively, the thin layers 200 may be formed to be sheets.

The pigment is fingerprint-proof. The pigment is formed of polyimide or Teflon.

In this state, the contact engagement portions 20 are slidably engaged with the rail contact portions 30 coated with the thin layers 200.

Referring to FIG. 14, when the sliding member 12 slides, the guide rails 12a also slide, that is, the rail contact portions 30 of the guide rails 12a also slide.

Because the contact engagement portions 20 have the thin layers 200 coated on their frictional surfaces, the thin layers 200 contact the contact engagement portions 20. Thus, friction is reduced and abrasion-proofness is increased. As a consequence, the movement and sensitivity of the sliding member 12 are improved.

As the guide rails 12a have the thin layers 200 formed of pigment, the product can be made more slim and smaller.

It may further be contemplated that sheet portions (not shown) are formed on the thin layers 200 coated on the rail contact portions 30. Thus, when the sheets are worn out by repeated sliding of the guide rails 12a for a long time, the thin layers 200 are then used, thus decreasing friction and increasing abrasion-proofness.

While the present invention has been particularly shown and described with reference to embodiments thereof, it will be understood by those of ordinary skill in the art that various changes in form and details may be made therein without departing from the spirit and scope of the present invention as defined by the following claims.

What is claimed is:

1. A sliding module of a portable communication device of the type having a main member, a sliding member for sliding in engagement with the main member, guide members formed at both ends of the main member, and guide rails slidably engaged with the guide rails, comprising:
a contact engagement portion provided at a guide member;
a rail contact portion provided at a guide rail; and
a sheet portion provided at the contact engagement portion to slide the guide rail in relation with the rail contact portion.

2. The sliding module of claim 1, wherein the contact engagement portion is extended to a predetermined length to contact the rail contact portion and comprises a smaller thickness than a thickness of an insert-molded portion of the guide member.

3. The sliding module of claim 1, wherein the sheet portion is shaped into “ [symbol] ” or “ [symbol] ”.

4. The sliding module of claim 1, wherein the sheet portion is formed of polyimide (PI) or Teflon.

5. The sliding module of claim 1, wherein the sheet portion includes first and second sheets that contact frictional surfaces of the rail contact portion.

6. The sliding module of claim 1, wherein a thickness of the sheet portion ranges from 0.03 to 0.05 mm.

7. A sliding module of a portable communication device of the type having a main member, a sliding member for sliding in engagement with the main member, guide members formed at both ends of the main member, and guide rails slidably engaged with the guide rails, comprising:
a contact engagement portion provided at a guide member;
a rail contact portion provided at a guide rail; and
a contact portion provided at the rail contact portion to slide the guide rail in relation to the contact engagement portion.

8. The sliding module of claim 7, wherein the contact portion is shaped into “ [symbol] ” or “ [symbol] ”.

9. The sliding module of claim 7, wherein the contact engagement portion includes a contact protrusion at a portion that contacts the contact portion.

10. The sliding module of claim 7, wherein the contact portion is substantially 0.05 mm thick.

11. A sliding module of a portable communication device of the type having a main member, a sliding member for sliding in engagement with the main member, guide members formed at both ends of the main member, and guide rails slidably engaged with the guide rails, comprising:
a contact engagement portion provided at a guide member;
a rail contact portion provided at a guide rail; and
a thin layer formed at the guide rail to slide the guide rail in relation to the contact engagement portion.

12. The sliding module of claim 11, wherein the thin layer is formed to be a sheet or the thin layer is formed of pigment.

13. The sliding module of claim 12, wherein the pigment is fingerprint-proof.

14. The sliding module of claim 12, wherein the pigment is formed of polyimide (PI) or Teflon.

15. The sliding module of claim 11, wherein the thin layer formed at the rail contact portion includes a sheet portion.
